(19) United States
(12) Patent Application Publication
(10) Pub. No.: US 2024/0274433 A1
(43) Pub. Date: Aug. 15, 2024

(54) SUBSTRATE PROCESSING METHOD AND SUBSTRATE PROCESSING APPARATUS

(71) Applicant: Tokyo Electron Limited, Tokyo (JP)

(72) Inventors: Tsuyoshi TSUNATORI, Nirasaki City (JP); Takayuki KOMIYA, Nirasaki City (JP)

(21) Appl. No.: 18/456,642

(22) Filed: Aug. 28, 2023

(30) Foreign Application Priority Data
Aug. 30, 2022 (JP) 2022-137232

(51) Int. Cl. H01L 21/02; C23C 16/04; C23C 16/34; C23C 16/455; C23C 16/50; H01J 37/32

(52) U.S. Cl. CPC H01L 21/0228; C23C 16/045; C23C 16/345; C23C 16/45542; C23C 16/50; H01J 37/32449; H01L 21/0217; H01L 21/02208; H01L 21/02211; H01L 21/02274; H01J 2237/332

(57) ABSTRACT

A substrate processing method of embedding a silicon nitride film in a recess formed in a surface of a substrate, includes repeating a cycle, the cycle including: a first operation of supplying a silicon precursor to form an adsorption layer of the silicon precursor on the substrate; a second operation of supplying a first nitrogen-containing gas and supplying a first power to an upper electrode to generate a first plasma, and exposing the substrate to the first plasma to nitride the adsorption layer and form the silicon nitride film; and a third operation of supplying a second nitrogen-containing gas and supplying a second power to a lower electrode to generate a second plasma different from the first plasma, and exposing the substrate to the second plasma to modify an upper portion of the recess and form an adsorption-inhibiting area.

### CROSS-REFERENCE TO RELATED APPLICATION

This application is based upon and claims the benefit of priority from Japanese Patent Application No. 2022-137232, filed on Aug. 30, 2022, the entire contents of which are incorporated herein by reference.

### TECHNICAL FIELD

The present disclosure relates to a substrate processing method and a substrate processing apparatus.

### BACKGROUND

Patent Document 1 discloses a method of manufacturing semiconductor devices. The method forms a film in a trench formed in a surface of a substrate by performing: a process of repeating a predetermined number of times a cycle in which an operation of supplying a halogen-based raw material gas to the substrate, an operation of supplying a reactive gas to the substrate, and an operation of supplying a reaction-inhibiting gas to the substrate under a first process condition are performed in a time division manner; and a process of repeating a predetermined number of times a cycle in which an operation of supplying the halogen-based raw material gas to the substrate, an operation of supplying the reactive gas to the substrate, and an operation of supplying the reaction-inhibiting gas to the substrate under a second process condition different from the first process condition are performed in a time division manner.

### PRIOR ART DOCUMENT

### Patent Document

Patent Document 1: Japanese Laid-Open Patent Publication No. 2017-069407

### SUMMARY

According to one embodiment of the present disclosure, there is provided a substrate processing method of embedding a silicon nitride film in a recess formed in a surface of a substrate, the method including: repeating a cycle, the cycle including: a first operation of supplying a silicon precursor to form an adsorption layer of the silicon precursor on the substrate; a second operation of supplying a first nitrogen-containing gas and supplying a first power to an upper electrode to generate a first plasma, and exposing the substrate to the first plasma to nitride the adsorption layer and form the silicon nitride film; and a third operation of supplying a second nitrogen-containing gas and supplying a second power to a lower electrode to generate a second plasma different from the first plasma, and exposing the substrate to the second plasma to modify an upper portion of the recess and form an adsorption-inhibiting area.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram illustrating a configuration example of a substrate processing apparatus.

FIG. 2 is a time chart illustrating an example of a SiN film formation process according to the present embodiment.

FIG. 3 is a time chart illustrating an example of a SiN film formation process according to Reference example.

FIG. 4 is a graph illustrating an example of a coverage of the formed SiN film.

FIG. 5 is a graph illustrating an example of a growth-per-cycle of the formed SiN film.

FIGS. 6A to 6C illustrate examples of schematic cross-sectional diagrams for explaining an operation of embedding a SiN film in a recess.

FIG. 7 is an example of a graph illustrating a relationship between the time taken for an operation of forming an adsorption-inhibiting area and the growth-per-cycle of the formed SiN film.

FIG. 8 is an example of a graph illustrating a relationship between the time taken for the operation of forming the adsorption-inhibiting area and optical film quality characteristics of the formed SiN film.

FIG. 9 is a time chart illustrating another example of a SiN film formation process according to the present embodiment.

### DETAILED DESCRIPTION

Hereinafter, embodiments for carrying out the present disclosure will be described with reference to the drawings. In each drawing, the same reference numerals will be given to the same components, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Substrate Processing Apparatus]

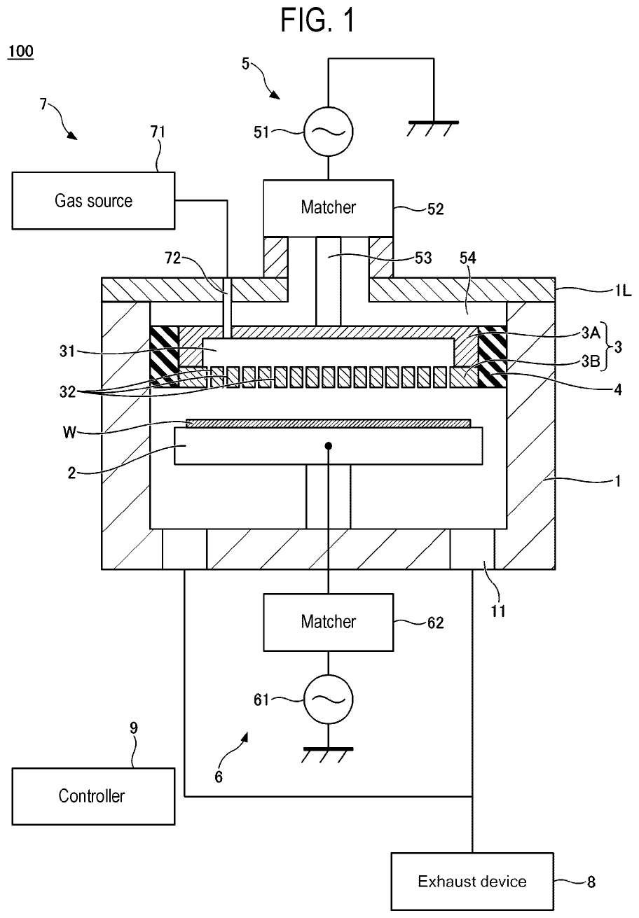

A plasma processing apparatus (substrate processing apparatus) 100 according to the present embodiment will be described with reference to FIG. 1. FIG. 1 is a schematic diagram illustrating a configuration example of the plasma processing apparatus 100. The plasma processing apparatus 100 forms a SiN film (silicon nitride film) on a substrate W such as a semiconductor wafer inside a processing container maintained in a depressurized state by a plasma enhanced atomic layer deposition (PE-ALD) method.

As illustrated in FIG. 1, the plasma processing apparatus 100 includes a processing container 1, a stage 2, an upper electrode 3, a dielectric cylinder 4, a first power supplier 5, a second power supplier 6, a gas supplier 7, an exhaust device 8, and a controller 9.

The plasma processing apparatus 100 includes the processing container 1 having an upper opening, a lid 1L that seals the upper opening of the processing container 1, the stage 2 (lower electrode) arranged inside the processing container 1, and a plasma generating source located above the stage 2. The plasma generating source includes the upper electrode 3 arranged to face the stage 2 and the dielectric cylinder 4 having an electromagnetic-wave radiation port (radio-frequency radiation port). Electromagnetic waves are radiated from a lower end face of the dielectric cylinder 4. The dielectric cylinder 4 is an introducer through which the electromagnetic wave (radio frequency) is introduced.

A processing target (substrate W) is placed on the stage 2. The substrate W is not particularly limited as long as it is subjected to a plasma processing, but examples of the substrate W may include a semiconductor substrate, an insulator substrate such as glass or alumina (Al₂O₃), and a metal substrate.

The first power supplier 5 supplies radio-frequency (RF) power to the processing container 1. The first power supplier 5 includes a first power supply 51, a first matcher 52, an antenna 53, and a waveguide 54. The first power supply 51 may be a power supply that generates RF power in a very high frequency (VHF) band. The RF power generated by the first power supply 51 has a frequency suitable for plasma generation. A frequency of the RF power supplied to the upper electrode 3 by the first power supply 51 may be 100 MHz or higher, specifically 220 MHz. The first power supply 51 is connected to the antenna 53 via the first matcher 52. The first matcher 52 includes a circuit for matching an output reactance of the first power supply 51 with a load reactance. The waveguide 54 is formed between the upper electrode 3, a lower surface of the lid 1L, and an inner surface of the processing container 1. The electromagnetic waves (for example, electromagnetic waves having a frequency higher than that of shortwaves such as VHF waves and UHF waves), which are input from the first power supply 51 to an upper portion of the upper electrode 3 via the first matcher 52 and the antenna 53, propagate radially and horizontally through the waveguide 54. When these electromagnetic waves hit the inner surface of the processing container 1, they propagate downward, and pass through the dielectric cylinder 4 to be emitted from a lower end surface thereof.

In a state in which a processing gas is introduced into the processing container 1 and the interior of the processing container 1 is depressurized by the exhaust device 8, which will be described later, to a pressure at which plasma generation is possible, when the electromagnetic waves are introduced into the processing container 1 from the first power supplier 5, plasma is generated below the upper electrode 3. A plasma area is located directly beneath the upper electrode 3. In addition, one end of the first power supply 51 is connected to the first matcher 52, while the other end is connected to a ground. Further, the antenna 53 may be any antenna capable of transmitting electromagnetic waves such as VHF waves may be employed, and as an electromagnetic-wave transmission component, a coaxial cable may be employed in addition to the waveguide.

The second power supplier 6 applies (supplies) radio-frequency (RF) power to the stage 2 serving as a lower electrode. The second power supplier 6 includes a second power supply 61 and a second matcher 62. The second power supply 61 may be a power supply that generates RF power in a medium frequency (MF) band or in a high frequency (HF) band. The RF power generated by the second power supply 61 has a frequency suitable for plasma generation. A frequency of the RF power supplied to the lower electrode (stage 2) by the second power supply 61 may fall within a range from 300 MHz to 30 MHz, specifically 13.56 MHz. The second power supply 61 is connected to the stage 2, which serves as the lower electrode, via the second matcher 62. The second matcher 62 includes a circuit for matching an output reactance of the second power supply 61 with a load reactance.

In a state in which a processing gas is introduced into the processing container 1 and the interior of the processing container 1 is depressurized by the exhaust device 8, which will be described later, to a pressure at which plasma generation is possible, when the RF power is applied (supplied) from the second power supplier 6 to the stage 2 serving as the lower electrode, a capacitively coupled plasma (CCP) is generated between the upper electrode 3 and the lower electrode (stage 2).

The gas supplier 7 supplies the processing gas into the processing container 1. The gas supplier 7 includes a gas source 71 and a supply pipe 72. The gas source 71 supplies the processing gas into the processing container 1 via the supply pipe 72. Specifically, the upper electrode 3 has a shower structure in which a processing gas distribution portion (internal space 31) is provided. The supply pipe 72 passes through the lid 1L, crosses the waveguide 54, and is fluidly connected to the internal space 31. The processing gas introduced into the internal space 31 is supplied to the interior of the processing container 1 via a plurality of processing gas ejection ports (gas holes 32) provided in a lower region of the upper electrode 3. The upper electrode 3 of this example takes a structure of a shower plate made of a metal, and includes the internal space 31 into which the processing gas is introduced, and the plurality of gas holes 32 which communicate the internal space 31 with the internal space of the processing container 1. The upper electrode 3 includes an upper metal member 3A having a recess on a lower surface thereof and a lower metal member 3B having the plurality of gas holes 32, and the internal space 31 is formed at the position of the recess between these metal members.

The exhaust device 8 exhausts the interior of the processing container 1. The exhaust device 8 exhausts the gas inside the processing container 1 to the outside via a gas exhaust port 11 of the processing container 1.

The controller 9 is, for example, a computer, and includes a central processing unit (CPU), a random access memory (RAM), a read only memory (ROM), an auxiliary storage device, and the like. The CPU operates based on programs stored in the ROM or the auxiliary storage device which may be a non-transitory computer-readable storage medium, and controls the operation of the plasma processing apparatus 100. The controller 9 may be provided inside or outside the plasma processing apparatus 100. When the controller 9 is provided outside the plasma processing apparatus 100, the controller 9 may control the plasma processing apparatus 100 by a communication means based on, for example, a wired or wireless manner.

### [Film Formation Processing Using Substrate Processing Apparatus]

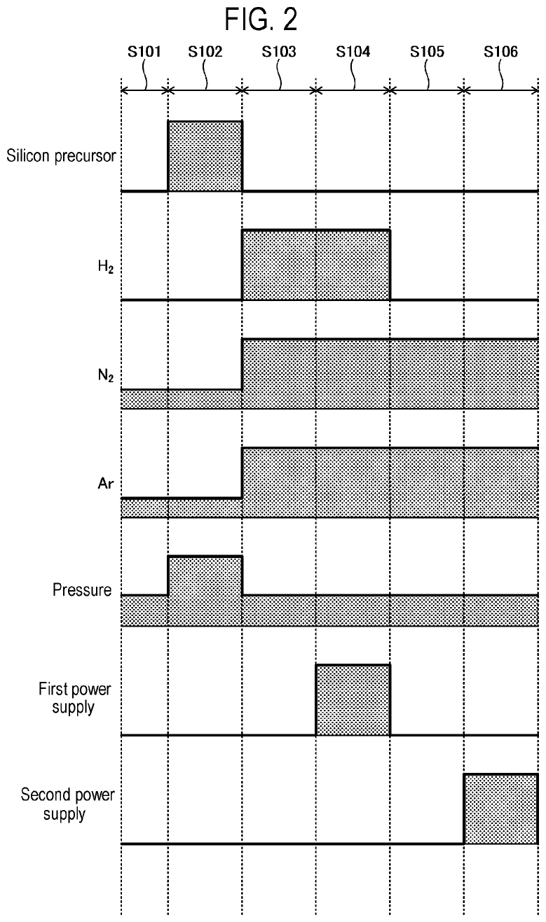

Next, an example of a SiN film formation process using the plasma processing apparatus 100 will be described with reference to FIG. 2.

FIG. 2 is a time chart illustrating an example of a SiN film formation process according to the present embodiment. The plasma processing apparatus 100 forms the SiN film on the substrate W by a PE-ALD process.

The PE-ALD process according to the present embodiment illustrated in FIG. 2 is a process of forming the SiN film with a desired film thickness on the substrate W by repeating a predetermined number of times a cycle including Operation S101 performing a purging, Operation (first operation) S102 supplying a silicon precursor gas, Operation S103 performing the purging, Operation (second operation) S104 performing a nitriding process, Operation S105 performing the purging, and Operation (third operation) S106 forming an adsorption-inhibiting area. In addition, FIG. 2 illustrates only one cycle. Further, an inert gas is continuously supplied from Operation S101 to Operation S106. The inert gas is selected from at least one of an Ar gas and a He gas. In the following, descriptions will be made under the assumption that the Ar gas is used as the inert gas. Further, a N₂ gas is continuously supplied from Operation S101 to Operation S106. Further, the N₂ gas is also used as a purge gas, a first nitrogen-containing gas, and a second nitrogen-containing gas, which will be described later.

Operation S101 performing the purging is an operation of purging gases and the like in a processing space of the processing container 1. In Operation S101 performing the purging, the controller 9 controls the gas supplier 7 to supply the N₂ gas from the gas source 71 into the processing space of the processing container 1 at a first flow rate and to supply the Ar gas as the inert gas at a second flow rate. Further, the controller 9 controls the exhaust device 8 to control an internal pressure of the processing space of the processing container 1 to a first pressure. Thus, the gases and like in the processing space of the processing container 1 are purged.

Operation S102 supplying the silicon raw material gas is an operation of supplying the silicon precursor gas (for example, DCS gas) into the processing space of the processing container 1. In Operation S102 supplying the silicon precursor gas, the controller 9 controls the gas supplier 7 to supply the silicon precursor gas from the gas source 71 into the processing space of the processing container 1. The silicon precursor is selected from at least one of halogenated silane, aminosilane, silylamine, and the like. In addition, in the following, descriptions will be made under the assumption that the dichlorosilane (DCS) gas is used as as the silicon precursor gas. Further, subsequent to Operation S101 performing the purging, the controller 9 controls the gas supplier 7 to supply the N₂ gas as the purge gas from the gas source 71 into the processing space of the processing container 1 at the first flow rate and to supply the Ar gas as the inert gas at the second flow rate. Further, the controller 9 controls the exhaust device 8 to control the internal pressure of the processing space of the processing container 1 to a second pressure. In addition, the second pressure is higher than the first pressure (second pressure>first pressure). Thus, the silicon precursor is adsorbed onto a surface of the substrate W so that an adsorption layer of the silicon precursor is formed on the surface of the substrate W. Specifically, adsorption sites to which the silicon precursor is adsorbed are formed on the surface of the substrate W. As the silicon precursor is adsorbed to the adsorption sites, the adsorption layer of the silicon precursor is formed on the surface of the substrate W.

Further, the internal pressure (second pressure) of the processing space in Operation S102 supplying the silicon precursor gas is higher than the internal pressure (first pressure) of the processing space in each of Operations S101 and S103 to S106. As described above, by increasing the internal pressure of the processing space in Operation S102 supplying the silicon precursor gas, the silicon precursor is properly adsorbed to the surface of the substrate W.

Further, the flow rate (first flow rate) of the N₂ gas in Operation S102 supplying the silicon precursor gas is smaller than a flow rate (third flow rate to be described later) of the N₂ gas in each of Operations S103 to S106. Further, the flow rate (second flow rate) of the Ar gas in Operation S102 supplying the silicon precursor gas is smaller than a flow rate (fourth flow rate to be described later) of the Ar gas in each of Operations S103 to S106. Further, the sum of the flow rate (first flow rate) of the N₂ gas and the flow rate (second flow rate) of the Ar gas in Operation S102 supplying the silicon precursor gas is smaller than the sum of the flow rate (third flow rate to be described later) of the N₂ gas and the flow rate (fourth flow rate to be described later) of the Ar gas in each of Operations S103 to S106. As described above, by decreasing the flow rates of the N₂ gas and the Ar gas in Operation S102 supplying the silicon precursor gas, a partial pressure of the silicon precursor gas may be increased so that the silicon precursor is properly adsorbed to the surface of the substrate W.

Operation S103 performing the purging is an operation of purging an excess of the silicon precursor gas and the like in the processing space of the processing container 1. In Operation S103 performing the purging, the controller 9 controls the gas supplier 7 to supply the N₂ gas from the gas source 71 into the processing space of the processing container 1 at the third flow rate and to supply the Ar gas as the inert gas at the fourth flow rate. In addition, the third flow rate is larger than the first flow rate (third flow rate>first flow rate). The fourth flow rate is larger than the second flow rate (fourth flow rate>second flow rate). Further, the controller 9 controls the exhaust device 8 to control the internal pressure of the processing space of the processing container 1 to the first pressure. Thus, the gases and the like in the processing space of the processing container 1 are purged. Further, in Operation S103 performing the purging, in order to prepare the subsequent Operation S104 performing the nitriding process, the controller 9 controls the gas supplier 7 to supply a first nitrogen-containing gas (a mixed gas of the H₂ gas and the N₂ gas), which will be described later, from the gas source 71 into the processing space of the processing chamber 1.

Operation S104 performing the nitriding process is an operation of supplying the first nitrogen-containing gas (for example, the mixed gas of the H₂ gas and the N₂ gas), supplying power to the upper electrode 3 to generate a first plasma, and exposing the substrate W to the first plasma to nitride the adsorption layer of the silicon precursor formed on the surface of the substrate W and form a silicon nitride film. In other words, Operation S104 is an operation of exciting the first nitrogen-containing gas with the first plasma. In addition, the first nitrogen-containing gas is also referred to as a reactive gas that reacts with the silicon precursor, or a nitriding gas that nitrides the silicon precursor. In Operation S104 performing the nitriding process, the controller 9 controls the gas supplier 7 to supply the first nitrogen-containing gas from the gas source 71 into the processing space of the processing container 1. The first nitrogen-containing gas is selected from at least one of a N₂ gas, a NH₃ gas, and a mixed gas of N₂ gas and H₂ gas. In addition, in the following, descriptions will be made under the assumption that the mixed gas of the H₂ gas and the N₂ gas is used as the first nitrogen-containing gas. In other words, subsequent to Operation S103 performing the purging, the controller 9 controls the gas supplier 7 to supply the first nitrogen-containing gas (the mixed gas of the H₂ gas and the N₂ gas) and the inert gas (Ar gas) from the gas source 71 into the processing space of the processing chamber 1. Further, the controller 9 controls the exhaust device 8 to control the internal pressure of the processing space of the processing container 1 to the first pressure. Further, the controller 9 controls the first power supply 51 to supply the RF power to the antenna 53. Thus, plasma is generated below the upper electrode 3. Thus, the adsorption layer of the silicon precursor on the surface of the substrate W is nitrided by active species (for example, N ions and N radicals) of the first nitrogen-containing gas to form the SiN film. Further, the adsorption sites to which the silicon precursor is adsorbed are formed on the surface of the substrate W. The adsorption sites are, for example, NHₓ-groups (N—H bonds, where x=1, 2).

Operation S105 performing the purging is an operation of purging an excess of the first nitrogen-containing gas and the like in the processing space of the processing container 1. In Operation S105 performing the purging, the controller 9 controls the gas supplier 7 to supply the N₂ gas from the gas source 71 into the processing space of the processing container 1 at the third flow rate and to supply the Ar gas as the inert gas at the fourth flow rate. Further, the controller 9 controls the exhaust device 8 to control the internal pressure of the processing space of the processing container 1 to the first pressure. Thus, the gases and the like in the processing space of the processing container 1 are purged. Further, in Operation S105 performing the purging, in order to prepare the subsequent Operation S106 forming the adsorption-inhibiting area, the controller 9 controls the gas supplier 7 to supply a second nitrogen-containing gas (N₂ gas), which will be described later, from the gas source 71 into the processing space of the processing chamber 1.

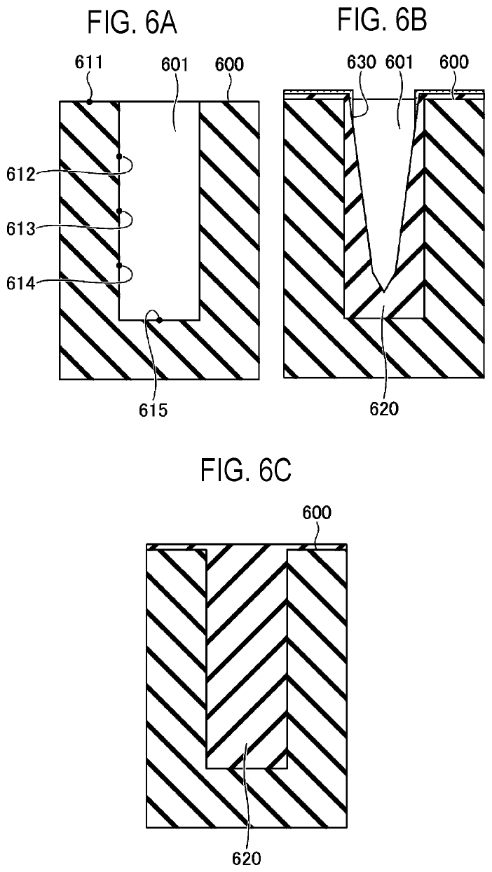

Operation S106 forming the adsorption-inhibiting area is an operation of supplying the second nitrogen-containing gas (for example, the N₂ gas), supplying power to the lower electrode (the stage 2) to generate a second plasma, and exposing the substrate W to the second plasma to modify an upper surface of a recess 601 (see FIG. 6A to be described later) formed on the surface of the substrate W and the vicinity of an opening of the recess 601, thus forming an adsorption-inhibiting area 630 (see FIG. 6B to be described later). In other words, Operation S106 is an operation of exciting the second nitrogen-containing gas with the second plasma. In addition, the second nitrogen-containing gas is also referred to as an inhibiting gas that forms the adsorption-inhibiting area. In Operation S106 forming the adsorption-inhibiting area, the controller 9 controls the gas supplier 7 to supply the second nitrogen-containing gas from the gas source 71 into the processing space of the processing container 1. The second nitrogen-containing gas is the N₂ gas. In other words, subsequent to Operation S105 performing the purging, the controller 9 controls the gas supplier 7 to supply the second nitrogen-containing gas (N₂ gas) and the inert gas (Ar gas) from the gas source 71 into the processing space of the processing chamber 1. Further, the controller 9 controls the exhaust device 8 to control the internal pressure of the processing space of the processing container 1 to the first pressure.

Further, the controller 9 controls the second power supply 61 to supply the RF power to the stage 2 as the lower electrode. In Operation S106, no plasma is generated by the first power supply 51. Thus, the surface of the substrate W is exposed to a N₂ plasma. Further, the surface of the substrate W is exposed to the N₂ plasma so that the adsorption-inhibiting area in which adsorption sites of the silicon precursor are reduced is formed.

By repeating the above-described cycle, the SiN film is formed on the substrate W.

In addition, the process of forming the SiN film using the plasma processing apparatus 100 is not limited to that illustration in FIG. 2. Operations S101, S103 and S105 performing the purging has been described to be provided between respective operations such as Operation S102 supplying the silicon precursor gas (first operation), Operation S104 performing the nitriding process (second operation), and Operation S106 forming the adsorption-inhibiting area (third operation), but the present disclosure is not limited thereto. For example, at least one of Operations S101, S103 and S105 performing the purging may be omitted.

Further, when a first cycle is defined to include Operations S101 to S104, the first cycle is repeated a predetermined number of times (for example, 5 times or 10 times), and subsequently, a second cycle including Operations S105 and S106 and returning to Operation S101 again is repeated. In other words, Operations S105 and S106 may be performed each time the first cycle including Operation S101 to Operation S104 is performed the predetermined number of times.

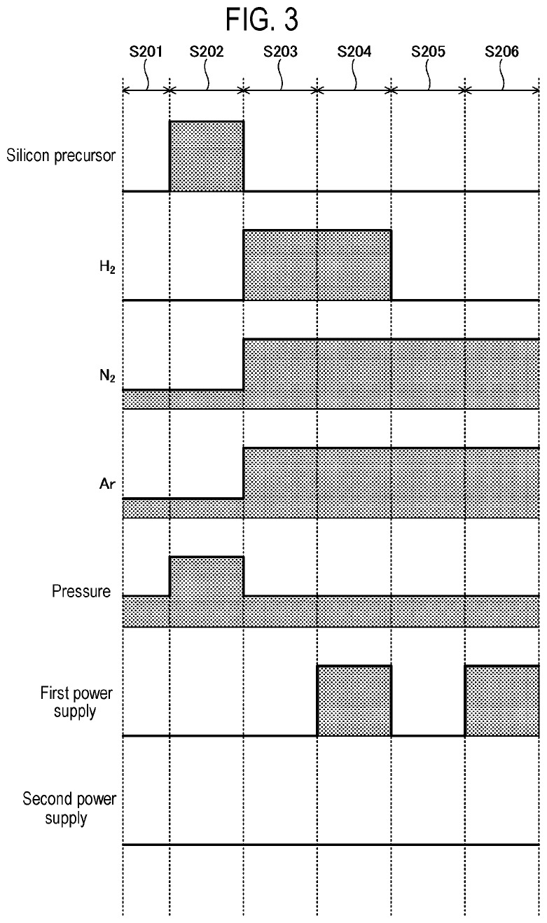

Next, another example of the SiN film formation process using the plasma processing apparatus 100 will be described with reference to FIG. 3.

FIG. 3 is a time chart illustrating an example of a SiN film formation process according to Reference example. The plasma processing apparatus 100 forms the SiN film on the substrate W by a PE-ALD process.

The PE-ALD process according to the present embodiment illustrated in FIG. 3 is a process of forming a SiN film with a desired film thickness on the substrate W by repeating a predetermined cycle including Operation S201 performing a purging, Operation S202 supplying a silicon precursor gas, Operation S203 performing the purging, Operation S204 performing a nitriding process, Operation S205 performing the purging, and Operation S206 forming an adsorption-inhibiting area. In addition, in FIG. 3, only one cycle is illustrated.

Here, Operations S201 to S205 illustrated in FIG. 3 are the same as Operations S101 to S105 illustrated in FIG. 2, and redundant descriptions thereof will be omitted.

Operation S206 forming the adsorption-inhibiting area is an operation of supplying the second nitrogen-containing gas (for example, N₂ gas) to generate plasma, thus forming the adsorption-inhibiting area. In Operation S104 performing the nitriding process, the controller 9 controls the gas supplier 7 to supply the second nitrogen-containing gas (N₂ gas) and the inert gas (Ar gas) from the gas source 71 into the processing space of the processing chamber 1. Further, the controller 9 controls the exhaust device 8 to control the internal pressure of the processing space of the processing container 1 to the first pressure. Further, the controller 9 controls the first power supply 51 to supply the RF power to the antenna 53.

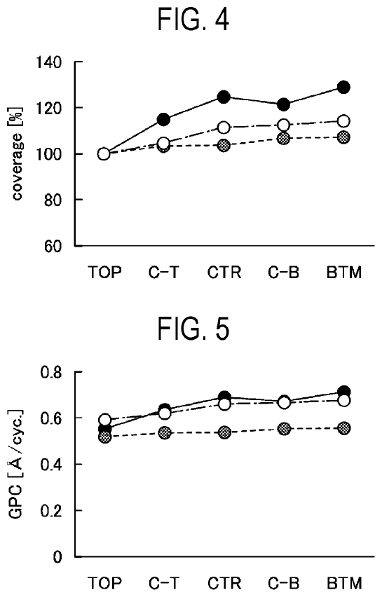

Next, examples of film formation results of the SiN film formation process according to the present embodiment and the SiN film formation process according to the Reference example will be described with reference to FIGS. 4 and 5 and FIGS. 6A to 6C. FIG. 4 is a graph illustrating an example of a coverage of the formed SiN film. FIG. 5 is a graph illustrating an example of a growth-per-cycle (GPC)) of the formed SiN film. FIGS. 6A to 6C are example schematic cross-sectional diagrams illustrating an operation of embedding the SiN film in the recess 601.

Here, as illustrated in FIG. 6A, the substrate W includes a film 600. The recess 601 such as a trench or hole is formed in the film 600. Here, a SiN film was formed on the substrate W having the recess 601 formed in the surface thereof by the SiN film formation process illustrated in FIG. 2 or FIG. 3.

Here, in FIGS. 4 and 5, “TOP” on the horizontal axis indicates the SiN film at an upper position of the recess 601 (position 611 in FIG. 6A). “CTR” on the horizontal axis indicates the SiN film at a central central sidewall position of the recess 601 in a sidewall height direction (position 613 in FIG. 6A). “BTM” on the horizontal axis indicates the SiN film at a lower position of the recess 601 (position 615 in FIG. 6A). “C-T” on the horizontal axis indicates the SiN film between the central sidewall position CTR of the recess 601 and the upper position TOP of the recess 601 in the sidewall height direction (position 612 in FIG. 6A). “C-B” on the horizontal axis indicates the SiN film between the central sidewall position CTR of the recess 601 and the lower position BTM of the recess 601 in the sidewall height direction (position 614 in FIG. 6A).

Further, in the graphs of FIGS. 4 and 5, solid lines and black markers show the results of the film formation process illustrated in FIG. 2. Here, in Operation S106 forming the adsorption-inhibiting area, the application time of the RF power by the second power supply 61 was set to 5 seconds. In the graphs, broken lines and hatched markers show the results of the film formation process illustrated in FIG. 3. Here, in Operation S206 forming the adsorption-inhibiting area, the application time of the RF power by the first power supply 51 was set to 1 seconds. In the graphs, one-dot dashed lines and hatched markers show the results of the film formation process illustrated in FIG. 3. Here, in Operation S206 forming the adsorption-inhibiting area, the application time of the RF power by the first power supply 51 was set to 5 seconds. Other main process conditions are as follows.

<Process Condition>

Pressure: 40 Pa to 400 Pa
Silicon precursor (DCS): 100 sccm to 1,000 sccm
Nitrogen-containing gas (H₂/N₂): 100 sccm to 1,000 sccm/
10 sccm to 100 sccm
Inert gas (Ar): 50 sccm to 2,000 sccm
First plasma: 500 W to 2,000 W
Second plasma: 50 W to 500 W

The vertical axis in FIG. 4 indicates the coverage [%] at each of the positions 611 to 615 normalized when the coverage at the upper position TOP of the recess 601 is set to 100%.

In Operation S206 forming the adsorption-inhibiting area as indicated by the one-dot dashed lines, as illustrated in the results of the film formation process illustrated in FIG. 3 in which the application time of the RF power by the first power supply 51 was set to 1 seconds, a difference in the coverages between the upper position (TOP) 611 of the recess 601 and the lower position (BTM) 615 of the recess 601 is small. Further, in Operation S206 forming the adsorption-inhibiting area as indicated by the broken lines, as illustrated in the results of the film formation process illustrated in FIG. 3 in which the application time of the RF power by the first power supply 51 was set to 5 seconds, a difference in the coverages between the upper position (TOP) 611 of the recess 601 and the lower position (BTM) 615 of the recess 601 becomes smaller.

In contrast, in Operation S106 forming the adsorption-inhibiting area as indicated by the solid lines, as illustrated in the results of the film formation process illustrated in FIG. 2 in which the application time of the RF power by the second power supply 61 was set to 5 seconds, a difference in the coverages between the upper position (TOP) 611 of the recess 601 and the lower position (BTM) 615 of the recess 601 becomes larger.

The vertical axis in FIG. 5 indicates growth-per-cycle (GPC): film thickness of SiN film per cycle) [Å/cyc.] at each of the positions 611 to 615.

The results of the film formation process illustrated in FIG. 2 in which the application time of the RF power by the second power supply 61 was set to 5 seconds in Operation S106 forming the adsorption-inhibiting area as indicated by the solid lines, show that a difference in growth-per-cycle between the upper position (TOP) 611 of the recess 601 and the lower position (BTM) 615 of the recess 601 is larger, compared to the results of the film formation process illustrated in FIG. 3 in which the application time of the RF power by the first power supply 51 was set to 1 seconds in Operation S206 forming the adsorption-inhibiting area as indicated by the one-dot dashed lines and the results of the film formation process illustrated in FIG. 3 in which the application time of the RF power by the first power supply 51 was set to 5 seconds in Operation S206 forming the adsorption-inhibiting area as indicated by the broken lines.

As described above, according to the film formation process illustrated in FIG. 2, as illustrated in FIG. 6B, the adsorption-inhibiting area 630 with reduced adsorption sites is formed on a upper surface of the film 600 and a sidewall upper portion of the recess 601. Thus, both the growth-per-cycle and the coverage increase at the lower position (BTM) 615 of the recess 601, compared to the upper position (TOP) 611 of the recess 601. Accordingly, by repeating the PE-ALD cycle, the growth-per-cycle on a sidewall lower portion of the recess 601 increases relatively, so that a SiN film 620 having a V-shaped cross-sectional shape is formed.

Thus, by repeating the film formation process illustrated in FIG. 2 a predetermined number of times, as illustrated in FIG. 6C, the SiN film 620 can be embedded in the recess 601 with no void.

Further, as the number of ALD cycles increases, the conditions for generating the second plasma in Operation S106 forming the adsorption-inhibiting area (third operation) are changed in a stepwise manner. Specifically, at least one of the power (RF power) to generate the second plasma, the supply amount of the second nitrogen-containing gas and the exposure time to the second plasma, and the supply amount of the second nitrogen-containing gas and the exposure time to the second plasma are changed (increased or decreased) in a stepwise manner.

In other words, as the number of ALD cycles increases and the embedding of the SiN film 620 progresses from the bottom surface of the recess 601, the aspect ratio of the recess 601 varies. Therefore, the range in which the adsorption-inhibiting area 630 is formed is changed by changing the conditions for generating the second plasma.

Here, when the number of ALD cycles reaches a predetermined number of times, the conditions for generating the second plasma are changed such that the range of the adsorption-inhibiting area 630 formed on the side surface of the recess 601 corresponds to only a shallower portion of the recess 601. Thus, as illustrated in FIG. 6B, the adsorption-inhibiting area 630 with reduced adsorption sites are formed on the upper surface of the film 600 and in the vicinity of the opening of the recess 601.

Specifically, changing the condition for generating the second plasma may reduce the power (RF power) of the second plasma. Further, the supply amount of the second nitrogen-containing gas may be reduced. Further, the irradiation time (exposure time) to the second plasma may be reduced. Further, at least 2 or more of these may be combined with each other.

Thereafter, the condition for generating the second plasma may be changed in a stepwise manner each time the number of ALD cycles reaches a predetermined number of times.

Thus, as illustrated in FIG. 6C, the SiN film 610 can be embedded in the recess 601 with no void.

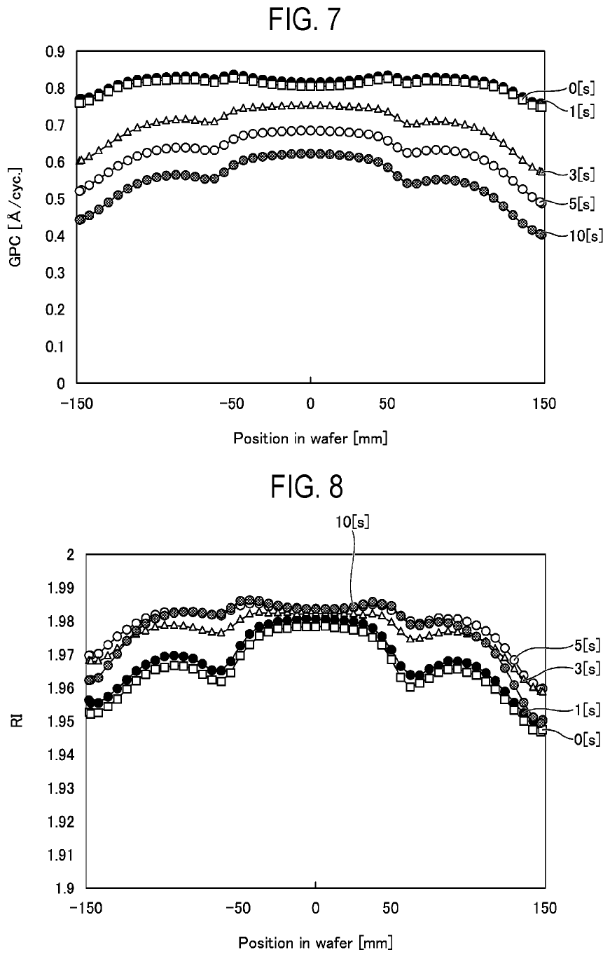

FIG. 7 is an exemplary graph illustrating a relationship between the time taken for the operation of forming the adsorption-inhibiting area (the application time of the RF power by the second power supply 61) and the growth-per-cycle of the formed SiN film in the film formation process illustrated in FIG. 2. The horizontal axis indicates the distance [mm] from the center of the substrate W when the center of the substrate W is set to 0 [mm]. The vertical axis represents the growth-per-cycle. Here, the film formation process was performed with the time taken for Operation S106 forming the adsorption-inhibiting area set to 0 [s], 1 [s], 3 [s], 5 [s], and 10 [s].

As illustrated in FIG. 7, the growth-per-cycle decreases as the time taken for Operation S106 forming the adsorption-inhibiting area increases. In other words, this shows that the adsorption inhibition effect increases.

FIG. 8 is an exemplary graph illustrating a relationship between the time taken for the operation of forming the adsorption-inhibiting area (the application time of the RF power by the second power supply 61) and the optical film quality characteristics of the formed SiN film in the film formation process illustrated in FIG. 2. The horizontal axis indicates the distance [mm] from the center of the substrate when the center of the substrate W is set to 0 [mm]. The vertical axis indicates the refractive index (RI) which is an index of film quality characteristics. In addition, the refractive index (RI) of a pure SiN film is, for example, around 2. The fact that the refractive index of a formed film is close to the refractive index (RI) of the pure SiN film indicates that the formed film is pure.

As illustrated in FIG. 8, it can be seen that the film quality of the SiN film is maintained even if the time taken for Operation S106 forming the adsorption-inhibiting area is lengthened. Further, the results of FIG. 8 show that the film quality of the SiN film is slightly improved as the time taken for Operation S106 forming the adsorption-inhibiting area is lengthened.

As described above, by the film formation process according to the present embodiment illustrated in FIG. 2, when embedding the SiN film in the substrate W having the recess 601, the growth-per-cycle is relatively higher at the sidewall lower portion of the recess 601, and the SiN film 620 having a V-shaped cross-section is formed. This makes it possible to embed the SiN film 620 in the recess 601 with no void.

Further, by the film formation process according to the present embodiment illustrated in FIG. 2, the second nitrogen-containing gas may be used as the inhibiting gas for forming the adsorption-inhibiting area 630 on the upper surface of the film 600 and on the sidewall upper portion of the recess 601. In other words, corrosion of the apparatus may be prevented by using the second nitrogen-containing gas which is a non-corrosive gas.

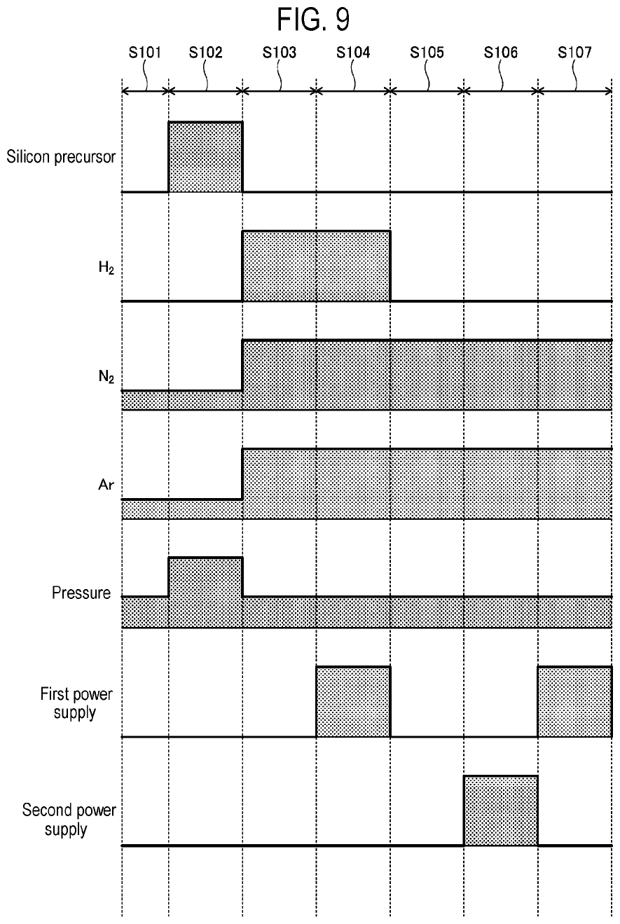

Next, another example of a SiN film formation process using the plasma processing apparatus 100 will be described with reference to FIG. 9.

FIG. 9 is a time chart illustrating another example of a SiN film formation process according to the present embodiment. The plasma processing apparatus 100 forms a SiN film on the substrate W by a PE-ALD process.

The PE-ALD process according to the present embodiment illustrated in FIG. 9 is a process of forming the SiN film with a desired film thickness on the substrate W by repeating a predetermined number of times a cycle including Operation S101 performing the purging, Operation S102 supplying the silicon precursor gas (first operation), Operation S103 performing the purging, Operation S104 performing the nitriding process (second operation), Operation S105 performing the purging, Operation S106 forming the adsorption-inhibiting area (third operation), and Operation S107 performing a modification (fourth operation). In FIG. 9, only one cycle is illustrated.

Here, Operations S101 to S106 illustrated in FIG. 9 are the same as Operations S101 to S106 illustrated in FIG. 2, and redundant descriptions thereof will be omitted.

Operation S107 performing the modification is an operation of supplying the second nitrogen-containing gas (for example, N₂ Gas) to generate a third plasma, and exposing the substrate W to the third plasma to modify the upper portion of the recess 601 formed on the surface of the substrate W. In other words, this operation is an operation of exciting the second nitrogen-containing gas with the third plasma. In Operation S107 performing the modification, the controller 9 controls the gas supplier 7 to supply the second nitrogen-containing gas from the gas source 71 into the processing space of the processing container 1. A N₂ gas may be used as the second nitrogen-containing gas. In addition, in the following, descriptions will be made under the assumption that the N₂ gas is used as the second nitrogen-containing gas. In other words, subsequent to Operation S105 performing the purging and Operation S106 forming the adsorption-inhibiting area, the controller 9 controls the gas supplier 7 to supply the second nitrogen-containing gas (N₂ gas) and the inert gas (Ar gas) from the gas source 71 into the processing space of the processing chamber 1. Further, the controller 9 controls the exhaust device 8 to control the internal pressure of the processing space of the processing container 1 to the first pressure. Further, the controller 9 controls the first power supply 51 to supply the RF power to the antenna 53.

By repeating the above-described cycle, the SiN film is formed on the substrate W.

Operation S107 performing the modification improves the etching resistance of the SiN film 620. This may ensure the embedding property of the SiN film 620 to the recess 601 and enhance the etching resistance of the SiN film 620.

In addition, the SiN film formation process using the plasma processing apparatus 100 is not limited to that illustrated in FIG. 9. For example, at least one of Operations S101, S103 and S105 performing the purging may be omitted. Further, a purging operation may be provided between Operation S106 forming the adsorption-inhibiting area and Operation S107 performing the modification.

Further, when a first cycle is defined to include Operations S101 to S104, a configuration may be employed in which the first cycle is repeated a predetermined number of times, subsequently, Operations S105 and S106 are performed and Operation S101 is performed again, the first cycle is repeated a predetermined number of times, and Operations S105 and S107 are performed and Operation S101 is performed again. In other words, one of Operations S106 and Operation S107 may be executed each time the first cycle including Operations S101 to S104 is performed the predetermined number of times.

According to the present disclosure in some embodiments, it is possible to provide a substrate processing method and a substrate processing apparatus for embedding a SiN film in a recess formed in a substrate.

Although the substrate processing method of the present embodiment using the plasma processing apparatus 100 has been described above, the present disclosure is not limited to the above-described embodiment and the like, and various modifications and improvements are possible within the scope of the gist of the present disclosure described in the claims.

What is claimed is:

1. A substrate processing method of embedding a silicon nitride film in a recess formed in a surface of a substrate, the substrate processing method comprising: repeating a cycle, the cycle comprising:
a first operation of supplying a silicon precursor to form an adsorption layer of the silicon precursor on the substrate;
a second operation of supplying a first nitrogen-containing gas and supplying a first power to an upper electrode to generate a first plasma, and exposing the substrate to the first plasma to nitride the adsorption layer and form the silicon nitride film; and
a third operation of supplying a second nitrogen-containing gas and supplying a second power to a lower electrode to generate a second plasma different from the first plasma, and exposing the substrate to the second plasma to modify an upper portion of the recess and form an adsorption-inhibiting area.

2. The substrate processing method of claim 1, wherein in the second operation, the first power supplied to the upper electrode has a frequency of 100 MHz or higher.

3. The substrate processing method of claim 2, wherein in the third operation, the second power supplied to the lower electrode has a frequency ranging from 300 kHz to 30 MHz.

4. The substrate processing method of claim 3, wherein an inert gas is continuously supplied in the first operation, the second operation, and the third operation.

5. The substrate processing method of claim 4, wherein the inert gas is selected from at least one of an Ar gas or a He gas.

6. The substrate processing method of claim 5, wherein a flow rate of the inert gas supplied in the first operation is smaller than a flow rate of the inert gas supplied in the second operation and the third operation.

7. The substrate processing method of claim 6, wherein the first nitrogen-containing gas is selected from at least one of a N₂ gas, a NH₃ gas, and a mixed gas of the N₂ gas and the H₂ gas.

8. The substrate processing method of claim 7, wherein the first nitrogen-containing gas is the mixed gas of the N₂ gas and the H₂ gas, and the second nitrogen-containing gas is the N₂ gas.

9. The substrate processing method of claim 1, wherein the first nitrogen-containing gas is selected from at least one of a N₂ gas, a NH₃ gas, and a mixed gas of the N₂ gas and the H₂ gas.

10. The substrate processing method of claim 1, further comprising: purging a gas inside a processing container between the first operation, the second operation, and the third operation.

11. The substrate processing method of claim 1, wherein the first operation and the second operation are defined as a first cycle, and the third operation is performed after repeating the first cycle a predetermined number of times.

12. The substrate processing method of claim 1, wherein, in the third operation, at least one of the second power to generate the second plasma, a supply amount of the second nitrogen-containing gas, and an exposure time to the second plasma are all increased or decreased in a stepwise manner according to an increase in a number of cycles.

13. The substrate processing method of claim 1, further comprising a fourth operation of supplying the second nitrogen-containing gas and an inert gas and supplying a third power to the upper electrode to generate a third plasma different from both the first plasma and the second plasma, and exposing the substrate to the third plasma to modify the silicon nitride film.

14. The substrate processing method of claim 13, wherein the second nitrogen-containing gas is a N₂ gas, and the inert gas is an Ar gas.

15. The substrate processing method of claim 1, wherein the silicon precursor is selected from at least one of halogenated silane, aminosilane, and silylamine.

16. The substrate processing method of claim 6, further comprising: purging a gas inside a processing container between the first operation, the second operation, and the third operation.

17. The substrate processing method of claim 6, wherein the first operation and the second operation are defined as a first cycle, and the third operation is performed after repeating the first cycle a predetermined number of times.

18. The substrate processing method of claim 6, wherein, in the third operation, at least one of the second power to generate the second plasma, a supply amount of the second nitrogen-containing gas, and an exposure time to the second plasma are all increased or decreased in a stepwise manner according to an increase in a number of cycles.

19. The substrate processing method of claim 6, further comprising a fourth operation of supplying the second nitrogen-containing gas and an inert gas and supplying a third power to the upper electrode to generate a third plasma different from both the first plasma and the second plasma, and exposing the substrate to the third plasma to modify the silicon nitride film.

20. A substrate processing apparatus comprising:
a stage provided inside a processing container and including a lower electrode;
an upper electrode arranged to face the stage;
a gas supplier configured to supply a gas to the processing container;
a first power supplier configured to supply a first power to the upper electrode to generate a first plasma;
a second power supplier configured to supply a second power to the lower electrode to generate a second plasma; and
a controller,
wherein the controller repeatedly executes a cycle including:
a first operation of supplying a silicon precursor to form an adsorption layer of the silicon precursor on a substrate having a recess formed in a surface of the substrate;
a second operation of supplying a first nitrogen-containing gas and supplying the first power to the upper electrode to generate the first plasma, and exposing the substrate to the first plasma to nitride the adsorption layer and form a silicon nitride film; and
a third operation of supplying a second nitrogen-containing gas and supplying the second power to the lower electrode to generate the second plasma different from the first plasma, and exposing the substrate to the second plasma to modify an upper portion of the recess and form an adsorption-inhibiting area.
